(19) United States
(12) Patent Application Publication
(10) Pub. No.: US 2011/0201160 A1
(43) Pub. Date: Aug. 18, 2011

(54) METAL-EMBEDDED SUBSTRATE AND METHOD FOR MANUFACTURING SEMICONDUCTOR PACKAGE USING THE SAME

(75) Inventor: Ki Il MOON, Gyeonggi-do (KR)

(73) Assignee: HYNIX SEMICONDUCTOR INC., Gyeonggi-do (KR)

(21) Appl. No.: 12/777,359

(22) Filed: May 11, 2010

(30) Foreign Application Priority Data
Feb. 18, 2010 (KR) 10-2010-0014565

(51) Int. Cl. H01L 21/50; H05K 1/18; H01L 21/56

(52) U.S. Cl. 438/124; 174/261; 257/E21.499; 257/E21.502

(57) ABSTRACT

A metal-embedded substrate includes a core layer having first circuit wiring lines with bond fingers formed on a first surface of the core layer and second circuit wiring lines with ball lands formed on a second surface of the core layer. Via wiring lines are formed so as to pass through the core layer and connect the first and second circuit wiring lines. Solder masks are selectively formed on the first and second surfaces of the core layer, including the first and second circuit wiring lines, so as to expose the bond fingers and the ball lands. Metal patterns are formed on the ball lands exposed through the solder masks. A metal active material is formed on the solder mask formed on the second surface of the core layer, and covers side surfaces of the metal patterns.

### CROSS-REFERENCE TO RELATED APPLICATIONS

The present application claims priority to Korean patent application number 10-2010-0014565 filed on Feb. 19, 2010, which is incorporated herein by reference in its entirety.

### BACKGROUND OF THE INVENTION

The present invention relates generally to a method for manufacturing a semiconductor package, and more particularly, to a metal-embedded substrate and a method for manufacturing a semiconductor package using the same.

In the semiconductor industry efforts are ongoing to decrease the size of a semiconductor package while also securing the electrical characteristics thereof. One example of a semiconductor package is the ball grid array package.

In the ball grid array package, a semiconductor chip is attached to a substrate, and bonding pads of the semiconductor chip and bond fingers of the substrate are connected to each other by means of bonding wires. An encapsulation member is formed over the upper surface of the substrate in order to seal the semiconductor chip and the bonding wires, and solder balls functioning as mounting means to an external circuit are attached to ball lands of the substrate.

The overall size of a ball grid array package can be reduced to the extent that it nearly approaches the size of the chip itself, and thus is advantageous in that the mounting area can be minimized. Further, when electrical connection to an external circuit is accomplished by way of the solder balls, enhanced electrical characteristics can be achieved through shortening of electrical signal transfer paths.

In the conventional art, a solder ball mounting process is necessary in the manufacturing process of the ball grid array. In this regard, as a ball size or a ball pitch decreases, it becomes difficult to realize appropriate equipment for the manufacturing process, and coplanarity is likely to deteriorate due to differences in the size of mounted balls.

Further, developments in the semiconductor industry have trended towards large capacity, high speed driving, and packages that are lightweight, thin, compact and miniaturized. To realize a thin package, a thin substrate should be used. However, in the course of handling a thin substrate, the use of a carrier is typically required, and additional costs are incurred accordingly.

### BRIEF SUMMARY OF THE INVENTION

Embodiments of the present invention include a metal-embedded substrate and a method for manufacturing a semiconductor package using the same, in which a solder ball mounting process can be omitted.

Also, embodiments of the present invention include a metal-embedded substrate and a method for manufacturing a semiconductor package using the same, which can prevent deterioration of coplanarity.

Further, embodiments of the present invention include a metal-embedded substrate and a method for manufacturing a semiconductor package using the same, which can eliminate the need of using a carrier substrate, thereby reducing the manufacturing cost.

An exemplary metal-embedded substrate according to the present invention comprises a core layer having a first surface and a second surface which faces away from the first surface; first circuit wiring lines formed on the first surface of the core layer and having bond fingers; second circuit wiring lines formed on the second surface of the core layer and having ball lands; via wiring lines formed through the core layer to connect the first circuit wiring lines and the second circuit wiring lines; solder masks formed on the first surface and the second surface of the core layer including the first circuit wiring lines and the second circuit wiring lines to respectively expose the bond fingers of the first circuit wiring lines and the ball lands of the second circuit wiring lines; metal patterns formed on the exposed ball lands; and a metal active material formed on the solder mask which is formed on the second surface of the core layer, to cover side surfaces of the metal patterns.

The metal active material may have solid properties at a temperature less than 200° C. and liquid properties at a temperature identical to or greater than 200° C.

The metal active material may contain rosin and a halogen activator.

An exemplary method for manufacturing a semiconductor package according to the present invention comprises the steps of preparing a substrate having an upper surface on which bond fingers are disposed and a lower surface on which ball lands are disposed; forming metal patterns on the ball lands of the substrate; forming a metal active material on the lower surface of the substrate to cover side surfaces of the metal patterns; disposing a semiconductor chip, which has bonding pads, on the upper surface of the substrate such that the bond fingers and the bonding pads are electrically connected; forming an encapsulation member to seal the upper surface of the substrate including the semiconductor chip; and conducting a reflow process for a resultant structure which is formed with the encapsulation member, thereby removing the metal active material and changing the metal patterns to have a circular sectional shape.

The substrate comprises a core layer having a first surface and a second surface which faces away from the first surface; first circuit wiring lines formed on the first surface of the core layer and having the bond fingers; second circuit wiring lines formed on the second surface of the core layer and having the ball lands; via wiring lines formed through the core layer to connect the first circuit wiring lines and the second circuit wiring lines; and solder masks formed on the first surface and the second surface of the core layer including the first circuit wiring lines and the second circuit wiring lines to respectively expose the bond fingers of the first circuit wiring lines and the ball lands of the second circuit wiring lines.

The step of forming the metal patterns may be implemented through plating.

The step of forming the metal patterns may include a process of depositing a metal layer and a process of etching the deposited metal layer.

The metal active material may solid properties at a temperature less than 200° C. and liquid properties at a temperature identical to or greater than 200° C.

The metal active material may contain rosin and a halogen activator.

The metal active material may be formed through squeezing a cream type material which contains rosin and a halogen activator.

The step of disposing the semiconductor chip, which has the bonding pads, on the upper surface of the substrate such that the bond fingers and the bonding pads are electrically connected may comprise the steps of attaching the semiconductor chip in a face-up type to the upper surface of the substrate; and wire-bonding the bond fingers of the substrate and the bonding pads of the semiconductor chip.

The step of disposing the semiconductor chip, which has the bonding pads, on the upper surface of the substrate such that the bond fingers and the bonding pads are electrically connected may be implemented through flip chip bonding.

The reflow process may be conducted in a furnace or an oven at a temperature of 200˜300° C.

After the step of conducting the reflow process, thereby removing the metal active material and changing the metal patterns to have the circular sectional shape, the method may further comprise the step of conducting a cleaning process such that the metal active material remaining after the reflow process can be removed.

The cleaning process may be conducted using a solvent or water.

### BRIEF DESCRIPTION OF THE DRAWINGS

FIG. 1 is a cross-sectional view showing a metal-embedded substrate in accordance with an embodiment of the present invention.

FIGS. 2A through 2E are cross-sectional views shown for illustrating the processes of a method for manufacturing a semiconductor package in accordance with an embodiment of the present invention.

FIG. 3 is a cross-sectional view shown for illustrating a method for manufacturing a semiconductor package in accordance with an embodiment of the present invention.

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

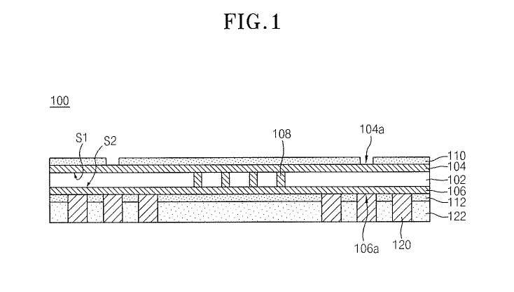

FIG. 1 is a cross-sectional view showing a metal-embedded substrate in accordance with an embodiment of the present invention.

Referring to FIG. 1, a metal-embedded substrate 100 in accordance with an embodiment of the present invention includes a core layer 102 having a first surface S1 and a second surface S2 facing away from the first surface S1. The metal-embedded substrate 100 further includes first circuit wiring lines 104 including bond fingers 104a formed on the first surface S1 of the core layer 102, and second circuit wiring lines 106 including ball lands 106a are formed on the second surface S2 of the core layer 102. Via wiring lines 108 are formed to pass through the first surface S1 of the core layer 102 and the second surface S2 of the core layer 102, so as to electrically connect the first circuit wiring lines 104 and the second circuit wiring lines 106. A first solder mask 110 and a second solder mask 112 are respectively formed on the first surface S1 of the core layer 102 and the first circuit wiring lines 104 and the second surface S2 of the core layer 102 and the second circuit wiring lines 106. The first solder mask 110 and the second solder mask 112 are formed so as to expose the bond fingers 104a of the first circuit wiring lines 104 and the ball lands 106a of the second circuit wiring lines 106, respectively.

Metal patterns 120 are formed on the ball lands 106a of the second circuit wiring lines 106, and a metal active material 122 is formed on the second solder mask 112 to cover the side surfaces of the metal patterns 120.

According to an embodiment, the metal patterns 120 serve as solder balls. As will be described below in detail, the metal patterns 120 are initially formed to have a shape which is substantially a quadrangular sectional shape, and are subsequently changed to have a sectional shape that is substantially circular after a reflow process is performed.

The metal active material 122 exhibits solid properties (e.g., the metal active material 122 will not flow) at a temperature less than 200° C. and liquid properties (e.g., the metal active material 122 will flow) at a temperature 200° C. or more, and functions to activate the melting of the metal patterns 120. For example, the metal active material 122 can comprise a material containing rosin and a halogen activator. However, it should be understood that the contents of the material above is by way of example only, and the present invention is not limited as such. In the metal active material above, the rosin functions to impart viscosity, and the halogen activator functions to activate the metal patterns 120. The metal active material 122 can be prepared, for example, to have a cream consistency, and can be formed on the second solder mask 112 through a squeezing process in such a way as to cover the side surfaces of the metal patterns 120.

Given an appropriate viscosity, the metal active material 122 can be formed on the second solder mask 112 using only the squeezing process in such a way as to cover the side surfaces of the metal patterns 120. Alternatively, in order to ensure stable handling of a finally obtained metal-embedded substrate, baking may be additionally conducted after the squeezing process so that a desired level of stiffness can be accomplished.

A liquid type flux can be employed as the metal active material 122 in place of the material containing the rosin and the halogen activator. The liquid type flux is widely used in the field of packages. In this case, although a generally used liquid type flux has a solids content of 3˜15%, the liquid type flux to be employed in the present invention should have a solids content of 50% or over.

As illustrated in the metal-embedded substrate constructed as described above, since the metal patterns perform the function of solder balls, a solder ball mounting process is not required according to an embodiment of the present invention. Accordingly, when a metal-embedded substrate according to an embodiment is used, the occurrence of defects associated with the solder ball mounting process can be prevented.

Also, in the metal-embedded substrate according to an embodiment, the metal patterns which perform the function of solder balls are formed through a deposition or plating process in such a way as to have desired volume and height. Therefore, when a metal-embedded substrate according to an embodiment of the present invention is used, known problems associated with the difficulties in realizing an appropriate equipment capable of accommodating reductions in ball size and ball pitch are overcome, and it is possible to prevent the deterioration of coplanarity of the metal-embedded substrate.

Further, in a metal-embedded substrate according to an embodiment of the present invention, the stiffness of the substrate is increased as a result of the metal patterns and the metal active material formed therein, and therefore, the substrate can be easily handled throughout the semiconductor package manufacturing procedure.

Next a method for manufacturing a semiconductor package using a metal-embedded substrate in accordance with an embodiment of the present invention will be described below in detail with reference to the attached drawings.

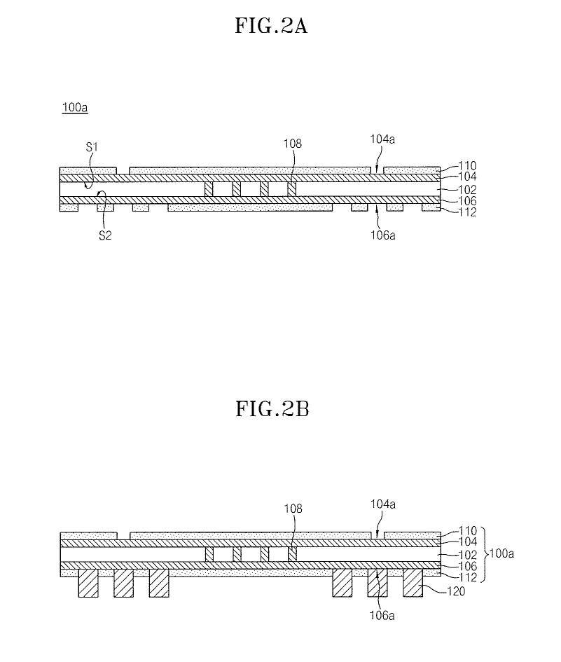

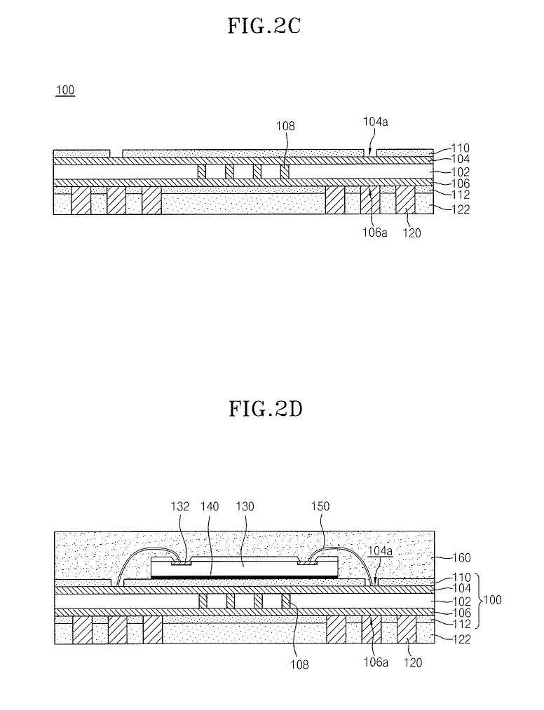

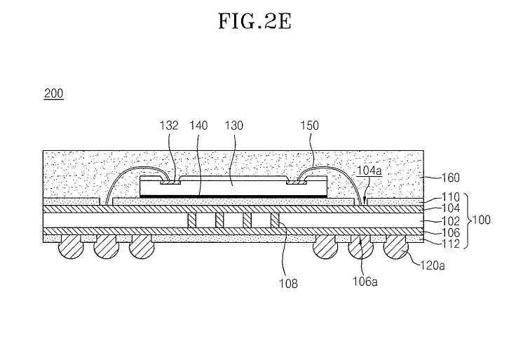

FIGS. 2A through 2E are cross-sectional views shown for illustrating the processes of a method for manufacturing a semiconductor package in accordance with an embodiment of the present invention.

Referring to FIG. 2A, a substrate 100a having bond fingers and ball lands is prepared. The substrate 100a has a structure as described above with regard to FIG. 1 prior to the formation of the metal patterns and the metal active material in the metal-embedded substrate, and can be understood as comprising a conventional printed circuit board, for example.

In detail, the substrate 100a includes a core layer 102 having a first surface S1 and a second surface S2 facing away from the first surface S1. The metal-embedded substrate 100 further includes first circuit wiring lines 104 including bond fingers 104a formed on the first surface S1 of the core layer 102, and second circuit wiring lines 106 including ball lands 106a formed on the second surface S2 of the core layer 102. Via wiring lines 108 are formed to pass through the first surface S1 of the core layer 102 and the second surface S2 of the core layer 102, so as to electrically connect the first circuit wiring lines 104 and the second circuit wiring lines 106. A first solder mask 110 and a second solder mask 112 are respectively formed on the first surface S1 of the core layer 102 and the first circuit wiring lines 104 and the second surface S2 of the core layer 102 and the second circuit wiring lines 106. The first solder mask 110 and the second solder mask 112 are formed so as to expose the bond fingers 104a of the first circuit wiring lines 104 and the ball lands 106a of the second circuit wiring lines 106, respectively.

Referring to FIG. 2B, metal patterns 120, which serve as solder balls, are formed on the ball lands 106a of the substrate 100a. The metal patterns 120 are formed on the exposed ball lands 106a, for example, through plating, so as to have a desired volume and height. For example, the metal patterns 120 may be formed to have a size corresponding to the exposed ball lands 106a and a height in the range of 20˜150 μm. Also, the metal patterns 120 may be formed to have a cross-sectional shape that is substantially quadrangular. In addition, after the metal patterns 120 are formed, unwanted portions of the metal patterns 120 may be removed through an etching process if necessary. Further, in addition to a plating process, the metal patterns 120 may also be selectively formed on desired portions of the substrate 100a, that is, on the exposed ball lands 106a, through sequentially conducting a process of depositing a metal layer and a process of etching the deposited metal layer. The formation of the metal patterns 120 is not limited in this way, as these exemplary processes are by way of example only.

While it is the metal patterns 120 are described and shown as being formed only on the ball lands 106a, it can be envisaged that the metal patterns 120 can also be formed on portions of the second solder mask 112 around the ball lands 106a as the occasion demands.

Referring to FIG. 2C, a metal active material 122 capable of activating the melting of the metal patterns 120 is formed on the lower surface of the substrate 100a having the metal patterns 120 formed thereon, and through this, a metal-embedded substrate 100 as described above with regard to FIG. 1 is constructed. In detail, the metal activation substrate 122 is formed on the second solder mask 112 and covers the side surfaces of the metal patterns 120. It is preferred that the metal active material 122 be formed to have the same height as the height of the metal patterns 120 which project from the second solder mask 112, as shown in FIG. 2C. This configuration ensures that the metal-embedded substrate 100 may be easily handled in subsequent processes.

According to an embodiment, the metal active material 122 is comprised of a material exhibiting solid properties at a temperature less than 200° C. and liquid properties at a temperature of 200° C. or more. For example, the metal active material 122 may be comprised of a cream type material capable of being squeezed containing rosin and a halogen activator. The rosin allows the metal active material 122 to have a desired viscosity, and the halogen activator activates the melting of the metal patterns 120.

The cream type metal active material 122, containing the rosin and the halogen activator, is formed on the second solder mask 112 through squeezing to cover the side surfaces of the metal patterns 120.

Since the viscosity of the metal active material 122 can be specified, the metal active material 122 can be formed on the second solder mask 112 to cover the side surfaces of the metal patterns 120 through only a squeezing process. In order to ensure stable handling of the metal-embedded substrate 100 in the subsequent processes, it is preferred that a baking process be conducted after the squeezing process to increase the stiffness of the metal-embedded substrate 100.

Alternatively, a liquid type flux can be employed as the metal active material 122 in place of the rosin and the halogen activator material above. The liquid type flux is widely used in the field of packages. It is preferred that the liquid type flux have a solids content of 50% or greater.

Referring to FIG. 2D, a semiconductor chip 130, which includes bonding pads 132 formed on a surface thereof, is attached to the upper surface of the metal-embedded substrate 100 using an adhesive member 140. As shown in FIG. 2D, the semiconductor chip 130 may be disposed in a “face-up” configuration, where the bonding pads 132 face away from the upper surface of the metal embedded substrate 100a. By way of example, the adhesive member 140 may include an adhesive paste or an adhesive film. The bonding pads 132 of the semiconductor chip 130 and the bond fingers 104a of the metal-embedded substrate 100 are connected by means of conductive wires 150 through, for example, a wire bonding process.

While FIG. 2D depicts the conductive wires 150 electrically connecting the bonding pads 132 of the semiconductor chip 130 and the bond fingers 104a of the metal-embedded substrate 100, it is conceivable that an alternative conductive material such as solders, pattern tapes, or the like may be used in place of the conductive wires 150.

An encapsulation member 160 is formed over the metal embedded substrate 100a and the semiconductor chip 130 so as to seal the upper surface of the metal-embedded substrate 100, having the semiconductor chip 130 attached thereto, and the conductive wires 150. The encapsulation member 160 is formed, for example, using an epoxy molding compound (EMC), through a molding process generally known in the art.

Referring to FIG. 2E, a reflow process is conducted for the resultant structure, which is formed with the encapsulation member 160. Through the reflow process, the metal active material 122 is removed, and metal patterns 120a having a circular sectional shape are formed, thereby completing the manufacture of a semiconductor package 200 in accordance with an embodiment of the present invention.

According to an embodiment, the reflow process is conducted in a furnace or an oven at a temperature in the range of 200˜300° C., preferably, at a temperature in the range of 220˜260° C.

As a result of the reflow process, the metal active material 122 is changed from a material exhibiting solid properties to a material exhibiting liquid properties, and is volatilized and removed with the lapse of time. In particular, in a course in which the metal active material 122 is volatilized and removed, the metal active material 122 activates the melting of the metal patterns 120, and as a result, the initial metal patterns 120, which have for example, a quadrangular cross-sectional shape, are changed to the metal patterns 120a having a substantially circular cross-sectional shape.

Therefore, in the method for manufacturing a semiconductor package in accordance with an embodiment of the present invention, it is not necessary to subsequently conduct a separate solder ball mounting process. Thus, it is possible to overcome known problems associated with the difficulties in realizing appropriate equipment capable accommodating reductions in ball size and ball pitch, and it is possible to prevent the deterioration of coplanarity.

Moreover, in a method for manufacturing a semiconductor package in accordance with an embodiment of the present invention, even for a thin substrate, the metal patterns and the metal active material formed on the substrate provide reinforcement, by which the substrate can be easily handled.

In addition, in a method for manufacturing a semiconductor package in accordance with an embodiment of the present invention, while often the metal active material is entirely removed through the reflow process, if a portion of the metal active material is not removed and remains, it is preferred that a cleaning process be subsequently conducted so that the remaining metal active material can be completely removed.

It is preferred that the cleaning process for completely removing the remaining metal active material be conducted using a solvent. As the case may be, the cleaning process may be conducted using water.

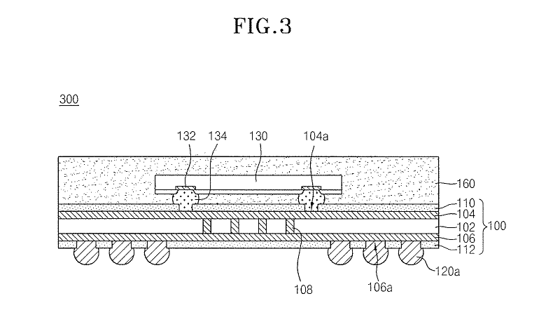

FIG. 3 is a cross-sectional view shown for illustrating a method for manufacturing a semiconductor package in accordance with an embodiment of the present invention. The same reference numerals will be used to refer to the same component elements.

Referring to FIG. 3, a semiconductor chip 130 and a metal-embedded substrate 100 are connected through a flip-chip bonding technique. In detail, the semiconductor chip 130 is disposed on the upper surface of the metal-embedded substrate 100 in a face-down configuration where the bonding pads 132 face the metal-embedded substrate. The bonding pads 132 of the semiconductor chip 130 and bond fingers 104a of the metal-embedded substrate 100 are electrically and physically connected by means of bumps 134.

Hence, a semiconductor package manufacture such as shown in FIG. 3, when compared to the semiconductor package constructed using the conductive wires such as shown in FIG. 2E, electrical paths can be reduced so as to ensure quick driving of the semiconductor package.

The remaining component parts are the same or similar as those of the FIG. 2E, and therefore, the repeated explanations thereof will be omitted herein.

Referring to FIG. 3, in a method for manufacturing a semiconductor package in accordance with an embodiment of the present invention, the same working effects as described above with reference to FIG. 2E can be achieved.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A metal-embedded substrate comprising:
a core layer having a first surface and a second surface which faces away from the first surface;
first circuit wiring lines formed on the first surface of the core layer and including bond fingers;
second circuit wiring lines formed on the second surface of the core layer and including ball lands;
via wiring lines passing through the first surface of the core layer and the second surface of the core layer and connecting the first circuit wiring lines and the second circuit wiring lines;
a first solder mask selectively formed on the first surface of the core layer and the first circuit wiring lines so as to expose the bond fingers of the first circuit wiring lines;
a second solder mask selectively formed on the second surface of the core layer and the second circuit wiring lines so as to expose the ball lands of the second circuit wiring lines;
metal patterns formed on the ball lands exposed through the second solder mask; and
a metal active material formed on the second solder mask and on side surfaces of the metal patterns, so as to cover the side surfaces of the metal patterns.

2. The metal-embedded substrate according to claim 1, wherein the metal active material comprises solid properties at a temperature less than 200° C. and liquid properties at a temperature equal to or exceeding 200° C.

3. The metal-embedded substrate according to claim 2, wherein the metal active material comprises rosin and a halogen activator.

4. A method for manufacturing a semiconductor package, comprising:
preparing a substrate having an upper surface on which bond fingers are disposed and a lower surface on which ball lands are disposed;
forming metal patterns on the ball lands of the substrate;
disposing a metal active material on the lower surface of the substrate so as to cover the side surfaces of the metal patterns;
disposing a semiconductor chip, which includes bonding pads formed thereon, on the upper surface of the substrate such that the bond fingers and the bonding pads are electrically connected;
forming an encapsulation member on the upper surface of the substrate including the semiconductor chip so as to encapsulate the semiconductor chip; and
conducting a reflow process on the substrate having the semiconductor chip and the encapsulation member formed thereon, such that the metal active material is removed and a sectional shape of the metal patterns becomes substantially circular.

5. The method according to claim 4, wherein the substrate comprises:
a core layer having a first surface and a second surface which faces away from the first surface;
first circuit wiring lines formed on the first surface of the core layer and including the bond fingers;
second circuit wiring lines formed on the second surface of the core layer and including the ball lands;
via wiring lines formed so as to pass through the first surface of the core layer and the second surface of the core layer, and connecting the first circuit wiring lines and the second circuit wiring lines;
a first solder mask selectively formed on the first surface of the core layer and the first circuit wiring lines so as to expose the bond fingers of the first circuit wiring lines; and
a second solder mask formed on the second surface of the core layer and the second circuit wiring lines so as to expose the ball lands of the second circuit wiring lines.

6. The method according to claim 4, wherein forming the metal patterns comprises plating.

7. The method according to claim 4, wherein forming the metal patterns comprises:
depositing a metal layer; and
etching the deposited metal layer.

8. The method according to claim 4, wherein the metal active material comprises solid properties at a temperature less than 200° C. and liquid properties at a temperature equal to or exceeding 200° C.

9. The method according to claim 8, wherein the metal active material comprises rosin and a halogen activator.

10. The method according to claim 9, wherein the metal active material is a cream type substance including rosin and a halogen activator and the metal active material is disposed through a squeezing process.

11. The method according to claim 4, wherein disposing the semiconductor chip on the upper surface of the substrate such that the bond fingers and the bonding pads are electrically connected comprises:
attaching the semiconductor chip in a face-up type on the upper surface of the substrate, such that the bonding pads face away from the upper surface of the substrate; and
wire-bonding the bond fingers of the substrate and the bonding pads of the semiconductor chip.

12. The method according to claim 4, wherein disposing the semiconductor chip on the upper surface of the substrate such that the bond fingers and the bonding pads are electrically connected comprises flip-chip bonding.

13. The method according to claim 4, wherein the reflow process is conducted in a furnace or an oven at a temperature in the range of 200° C. to 300° C.

14. The method according to claim 4, further comprising:
conducting a cleaning process to remove portions of the metal active material remaining after the reflow process.

15. The method according to claim 14, wherein the cleaning process is conducted using a solvent or water.
